(19) United States
(12) Patent Application Publication
(10) Pub. No.: US 2006/0236941 A1
(43) Pub. Date: Oct. 26, 2006

(54) Passive wafer support for particle free wafer acceleration

(75) Inventor: Harald Herchen, Los Altos, CA (US)

Correspondence Address: PATTERSON & SHERIDAN, LLP, 3040 POST OAK BOULEVARD, SUITE 1500, HOUSTON, TX, 77056, US

(73) Assignee: Applied Materials, Inc.

(21) Appl. No.: 11/336,471

(22) Filed: Jan. 20, 2006

Related U.S. Application Data
(63) Continuation-in-part of application No. 11/111,155, filed on Apr. 20, 2005.

(51) Int. Cl. B65G 25/00; C23C 16/00; H01L 21/306

(52) U.S. Cl. 118/728; 414/147; 156/345.51

(57) ABSTRACT

The present invention provides an apparatus and a method of handling and transferring substrate in reduced particle contamination and thermal stress, as well as increased speed. One embodiment of the present invention provides an apparatus for handling a substrate. The apparatus comprises a support plate, and at least one pad protruding an upper surface of the support plate. The pad is configured to support a backside of the substrate so that the backside of the substrate is a first distance away from the upper surface of the support plate. The thermal resistance of the pad is substantially equal to the thermal resistance of the medium between the substrate and the upper surface.

### CROSS-REFERENCE TO RELATED APPLICATIONS

This application is continuation in part of U.S. patent application Ser. No. 11/111,155, filed on Apr. 20, 2005, entitled “Purged Vacuum Chuck with Proximity Pins”, which is herein incorporated by reference.

### BACKGROUND OF THE INVENTION

1. Field of the Invention

Embodiments of the present invention generally relate to apparatus and method for handling semiconductor substrates.

2. Description of the Related Art

In modern semiconductor processing, multilayered features are fabricated on semiconductor substrates in a cleanroom environment using specific processing recipes having many processing steps. A semiconductor process system may include single process chambers and cluster tools which integrate a number of process chambers to perform a sequential processing steps without removing substrates from a highly controlled processing environment. The process chambers may include, for example, substrate preconditioning chambers, cleaning chambers, bake chambers, chill chambers, chemical vapor deposition chambers, physical vapor deposition chambers, etch chambers, electrochemical plating chambers, and the like. The substrates being processed are generally handled and transferred from one chamber to another by robots or other substrate handling devices. The transferring and handling steps are critical to process quality and throughput.

As the semiconductor industry develops, the size of substrates becomes larger and larger; the size of features becomes smaller and smaller; at the same time, the requirement for throughput becomes higher and higher. As a result, there is a demand for substrate handling and transferring tools of higher precision, increased speed, less particle contamination, and less mechanical and/or thermal stress.

To address the issue of particle contamination generated from contact, contact area is decreased as much as possible, and friction between substrate and substrate support has been decreased too. For example, substrates are usually supported on the backside by as few as three pins. However, since the substrate is only supported by a few pins, the substrate is likely to deform because of gravity and the support pressure is increased which may lead back to particle generation. Additionally, decreased friction introduces a problem of slippage, where a substrate will slide over a substrate support during transferring losing the precise positioning crucial to the semiconductor process. In some cases, vacuum chucks and mechanical gripping systems are added to substrate handling devices to avoid slippage. Consequently, the system becomes more complicated and contact area becomes larger and more particle contaminations are introduced.

Thermal stress also becomes a problem especially handling a substrate after a process performed in an elevated temperature. In the one hand, the substrate is not cooled down uniformly because the thermal resistance of the contact area is generally different from where there is no contact. In the other hand, the substrate may shrink in size while cooling down, thus introducing friction, slippage, and deformation, especially for substrates of large size.

FIG. 1 illustrates a schematic view of an exemplary integrated thermal unit 10 where substrate handling and transferring requires low particle contamination, reduced thermal stress and increased speed is required. A detailed description of an integrated thermal unit may be found in United States Patent Application entitled “Integrated Thermal Unit Having Bake and Chill Plates”, attorney docket number A9999/T60600, which is herein incorporated by reference.

The integrated thermal unit 10 comprises an enclosed housing 40 on which shutters 34a and 34b are disposed and configured for transferring substrates into and out of the integrated thermal unit 10 respectively. A bake station 12 for baking substrates, a chill station 14 for precisely chilling substrates, and a shuttle station 16 for transferring substrates between the bake station 12 and the chill station 14 as needed are disposed inside the enclosed housing 40 in a linear arrangement.

The shuttle station 16 comprises a shuttle plate 18 configured to move along a track 48 and transfer a substrate among the bake station 12, the chill station 14, and the shuttle station 16. A lift pin assembly 36 is configured to pick-up a substrate from the shuttle plate 18 or load a substrate on the shuttle plate 18.

The bake station 12 comprises a bake plate 20, a clam shell enclosure 22, a chill base 24, and a lift pin assembly 38. The bake plate 20 is movable between a loading position (shown in FIG. 1) and a heating position in which the bake plate 20 is urged into the clam shell enclosure 22 by a motorized lift 28. The chill base 24 is configured to cool the bake plate 20 rapidly from a higher, bake temperature to a lower, substrate receiving temperature after a bake step. The lift pin assembly 38 is configured to load/unload substrates to/from the shuttle plate 18 and the bake plate 20.

The chill station 14 comprises a precision chill base 30 and a lift pin assembly 37 configured to load/unload substrates to/from the shuttle plate 18 and the precision chill base 30.

An exemplary processing sequence for the integrated thermal unit 10 may include: loading a substrate onto the lift pin assembly 36 through shutter 34a, picking up the substrate by the shuttle plate 18, transferring the substrate to the bake station 12 by the shuttle plate 18, picking up the substrate by the lift pin assembly 38, returning the shuttle plate 18 to the shuttle station 16, raising the bake plate 20 and moving the substrate into the clam shell enclosure 22, baking the substrate, lowering the bake plate 20, raising the lift pin assembly 38 to pick up the baked substrate, moving the shuttle plate 18 to the bake station 12, loading baked substrate on the shuttle plate 18, transferring the baked substrate to the chill station 14; rising the lift pin assembly 37 to pick up the baked substrate, returning the shuttle plate 18 to the shuttle station 16, loading the baked substrate on the precision chill plate 30 by lowering the lift pin assembly 37, raising the lift pin assembly 37 to pick up the chilled substrate, transferring the substrate out of the thermal unit 10 via the shutter 34b.

FIGS. 2A-2B illustrate a shuttle plate 80 of prior art which may be used in place of the shuttle plate 18 in the integrated thermal unit 10 of FIG. 1. The shuttle plate 80 includes a plate body 81 and an adapter 83 configured to coupled the plate body 81 to a movement mechanism. Two slots 84 and 85 are formed in the plate body 81 and configured to accommodate lift pins for loading and unloading a substrate. A plurality of proximity pins 82 are disposed on an upper surface of the plate body 81 and are configured to support a substrate 88 thereon (as shown in FIG. 2B) to reduce contact area and particle generation. Suitable material for the proximity pins 82 is not easily abraded by the interaction with the backside of the substrate. The proximity pins 82 are usually made of sapphire, or other suitable material such as diamond, diamond-like carbon, silicon dioxide, silicon, a metal, and a polymeric material. However, the friction between the proximity pins 82 and the substrate 88 is generally not large enough to keep the substrate 88 from sliding especially when the shuttle plate 80 is accelerating or deaccelerating horizontally. Therefore, a plurality of pocket pins 87 are disposed around a receiving area 86 to keep the substrate 88 from sliding out of position. The pocket pins 87, however, contact the side of the substrate 88 which may cause extra particle contamination. When the substrate is substantially smaller than the receiving area 86, the substrate may slide a good length before hitting the pocket pins 87 and controlling the position of the substrate becomes difficult.

As described in the exemplary processing sequence, the shuttle plate 18 also transfers the baked substrate to the chill station 14. Since the environment is cooler than the baked substrate, the baked substrate is being cooled down while transferred by the shuttle plate 18. For a shuttle plate constructed like the shuttle plate 80, a baked substrate may not cool down evenly between the areas contacting the proximity pins and the areas exposed directly to the environment, thus causing thermal or even mechanical stress.

In conclusion, a shuttle plate of prior art are susceptible to thermal stress, particle contamination and slippage.

Therefore, there exists a need for apparatus and method of handling and transferring substrate in reduced particle contamination and thermal stress, as well as increased speed.

### SUMMARY OF THE INVENTION

Embodiment of the present invention generally provide an apparatus and a method for handling semiconductor substrates.

One embodiment of the present invention provides an apparatus for handling a substrate. The apparatus comprises a support plate, and at least one pad protruding an upper surface of the support plate wherein the pad is configured to support a backside of the substrate so that the backside of the substrate is a first distance away from the upper surface of the support plate, and a thermal resistance of the pad is substantially equal to a thermal resistance of a medium between the substrate and the upper surface.

Another embodiment of the present invention provides an apparatus for supporting and handling a substrate. The apparatus comprises a support plate and a plurality of pads formed on an upper surface of the support plate and configured to support the substrate, wherein the plurality of pads are made of an elastomer having fluorine as a major constituent.

Yet another embodiment of the present invention provides a method for handling a substrate. The method comprises providing a support plate having at least one pad formed an upper surface and a substantially uniform thermal resistance across the upper surface, positioning the substrate on the at least one pad, and transferring the substrate by moving the support plate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a schematic view of an exemplary integrated thermal unit that requires substrate handling and transferring.

FIG. 2A illustrates a shuttle plate of prior art for transferring a substrate.

FIG. 2B illustrates a partial sectional view of the shuttle plate shown in FIG. 2A.

FIG. 3 is a schematic view of one embodiment of a shuttle plate of the present invention.

FIG. 4A illustrates a sectional view of the shuttle plate of FIG. 3 in accordance with a lift pin assembly.

FIG. 4B is an enlarged view of the shuttle plate of FIG. 4A.

FIG. 5A-D illustrate an exemplary embodiment of manufacturing substrate pads of the present invention.

FIG. 6 illustrates one embodiment of a shuttle plate of the present invention.

FIG. 7 illustrate one embodiment of a shuttle plate of the present invention.

FIG. 8 illustrates a top view of the shuttle plate of FIG. 7.

FIG. 9 illustrates one embodiment of a shuttle plate of the present invention.

### DETAILED DESCRIPTION OF THE PREFERRED EMBODIMENT

Embodiments of the invention generally provide a substrate support plate having thin pads of elastomer which has high static friction coefficient and affords lack of residue. The thin pads are configured to keep a substrate from touching the substrate support plate. The thickness of the thin pads are designed such that the thermal resistance of the thin pads are substantially equal to the thermal resistance of the air gap between the substrate support plate and the substrate supported by the thin pads. Thus, the substrate support plate of the present invention provides high friction between the substrate and the supporting surface, low particle generation, and substantially uniform heat transfer property.

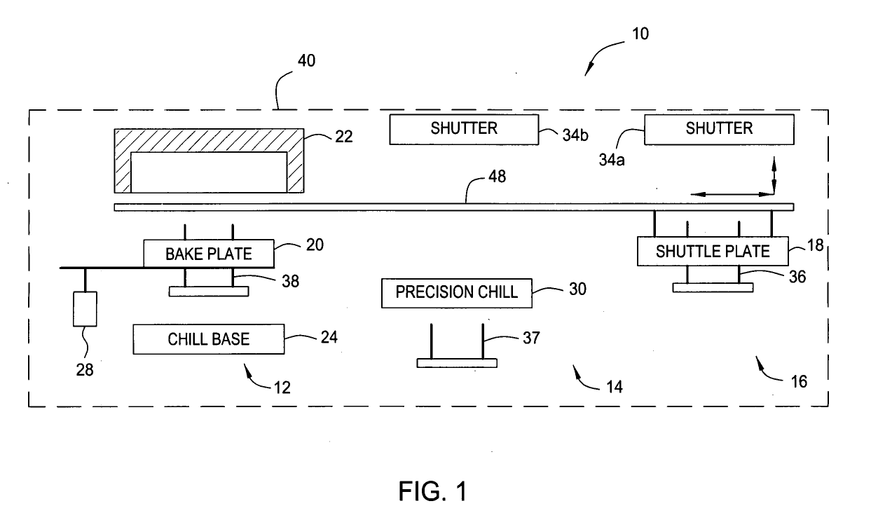

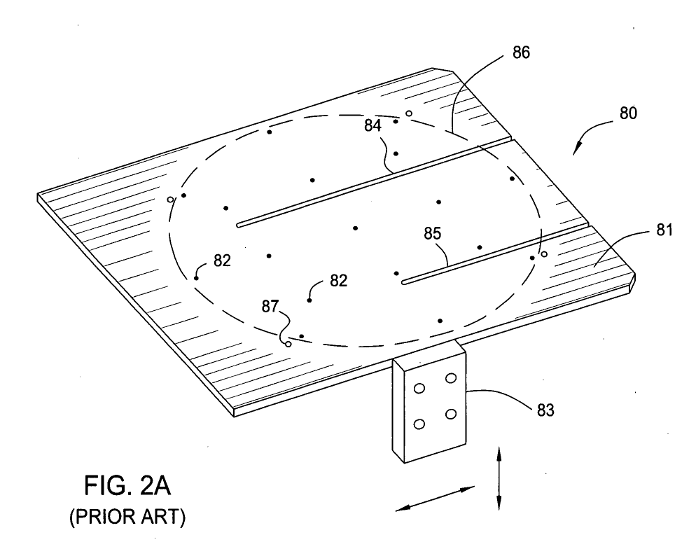

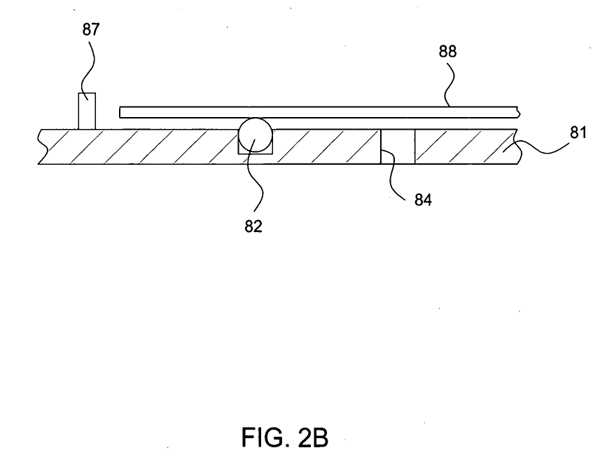

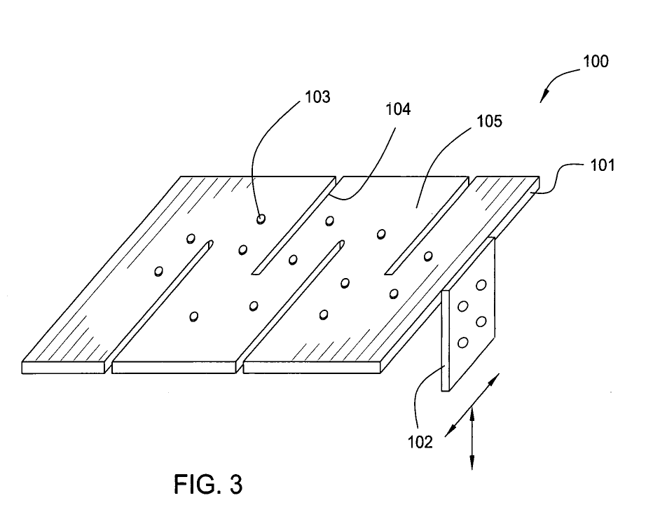

FIG. 3 is a schematic view of one embodiment of a shuttle plate 100 of the present invention. The shuttle plate 100 is configured to support and transfer a substrate in a semiconductor processing system, such as the integrated thermal unit 10 shown in FIG. 1.

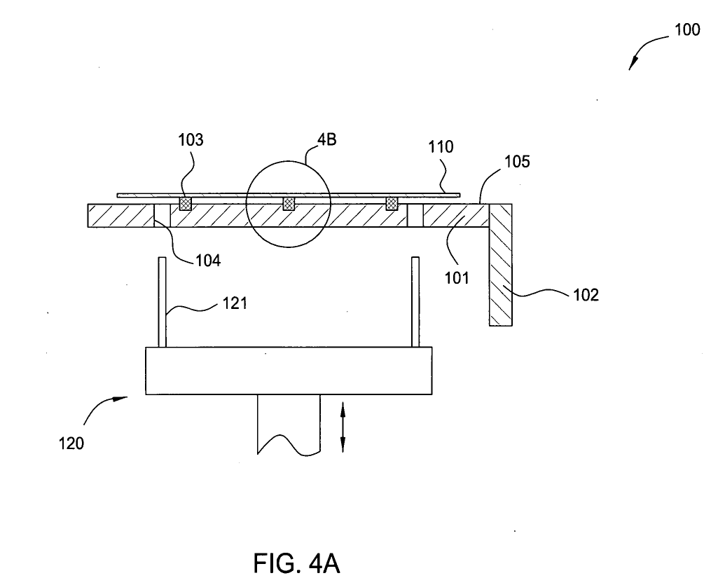

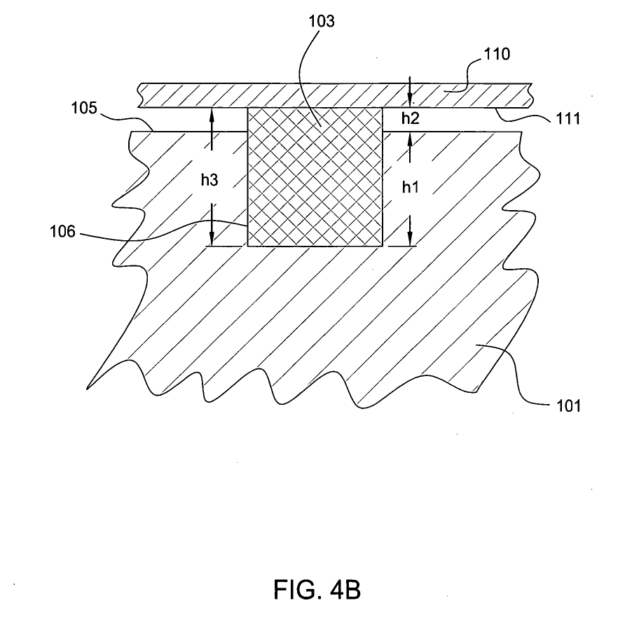

The shuttle plate 100 generally comprises a plate body 101 coupled to an adaptor 102. The adapter 102 is configured to transfer motions to the plate body 101. A plurality of substrate pads 103 protrude by the same level of height from an upper surface 105 of the plate body 101. In one embodiment, each of the plurality of substrate pads 103 has a circular upper surface of between 0.3 mm and 3 mm in diameter. The plurality of substrate pads 103 are configured to support a substrate 110 above the upper surface 105 as shown in FIG. 4A, which is a sectional view of the shuttle plate of FIG. 3 in accordance with a lift pin assembly 120. Referring back to FIG. 3, two pairs of slots 104 are formed on the plate body 101, opening to two opposite sides of the plate body 101. The slots 104 are configured to accommodate lift pins 121 of the lift pin assembly 120, as shown in FIG. 4A. The two pairs of slots 104 enable the shuttle plate 100 be compatible with lift pins located at two sides of the shuttle plate 100.

The plate body 101 may be made of aluminum coated with a polymer, for example Teflon® polymer manufactured by Dupont of Wilmington, Del., or Tufram® polymer manufactured by General Magnaplate Corporations of Linden, N.J. In alternative embodiments, the plate body 101 may be fabricated from stainless steel, silicon carbide, copper, graphite, aluminum nitride, aluminum oxide, boron nitride or combination/laminates of these materials.

In one embodiment, the substrate pads 103 are generally made from an elastomeric polymer having fluorine as a major constituent. Flourine provides high static and dynamic friction coefficient to an elastomer. Sapphire balls or similar low contact surface used in the state-of-the-art substrate handling systems provide low particle contamination during contact. However, sapphire balls and similar materials have relatively low friction coefficients. For example, sapphire has a static friction coefficient of about 0.4 against silicon and a dynamic friction coefficient of about 0.01. In many situations, vacuum or electrostatic attraction is needed to secure the substrate supported by these low friction materials, thus, increasing system complexity. Fluorinated elastomer generally has similar low particle properties as sapphire, and a static friction coefficient of about 1.66(dry)/2.49(wet) and a dynamic friction coefficient of about 0.42(dry)/0.41(wet). Therefore, the substrate pads 103 of present invention provides about 40 times more dynamic friction and about a factor of 4 for static friction to a substrate supported thereon compared to the state-of-the-art substrate contact surfaces. In one aspect, the shuttle plate 100 of the present invention is capable of accelerating or deaccelerating a substrate at a rate of about 0.5 g to 0.8 g via the friction from the substrate pads 103 only. Extra securing mechanism, such as vacuum, electrostatic attraction, and mechanical gripping, may be eliminated from the system, therefore, increases reliability of the system.

In another embodiment, the substrate pads 103 are made from an elastomeric polymer having fluorine as a major constituent and with no inorganic or non-fluoridated filler. Elastomeric material used in supporting substrates typically has an inorganic filler, such as silica, barium sulphate, or titanium dioxide. These fillers are micron sized or larger particles, hence leading to a particle source. The elstomeric polymer used to form the substrate pads 103 generally has a nanometer sized organic filler which essentially eliminates a particle source. Therefore, the contact area between the substrate and the substrate pads 103 may be increased and the pressure of contact decreased. A suitable material for the substrate pads 103 may be a perfluoroelastomer, which has a backbone comprises long chains of carbon atoms covalently bonded to fluorine atoms, and totally organic and fully fluoridated nanofillers, for example G67P from Perlast®.

FIG. 4B is an enlarged view the shuttle plate of FIG. 4A. As shown in FIG. 4B, each of the substrate pads 103 is positioned inside a recess 106 having a height of h1 formed on the upper surface 105 of the plate body 101. The substrate pads 103 protrude the upper surface 105 by a height of h2 so that there is a gap of h2 between the upper surface 105 and a back side 111 of the substrate 110 supported thereon. The total height h3 of the substrate pads 103 is the summation of h1 and h2.

Since the air is generally a better insulator for heat than the materials used to build substrate pads in a substrate support, the substrate pads may be designed to have a substantially equal thermal resistance as that of the air gap by choosing a sufficient thickness for the substrate pads, wherein the thermal resistance of a structure is defined as temperature difference across the structure when a unit of heat energy flows through unit area of the structure in unit time. Therefore, a uniform heat transfer across a substrate being supported may be achieved by choosing a sufficient thickness for the substrate pads, which are mostly recessed into the support structure. The state-of-the-art approaches do not compensate for the differences in thermal conductivity of the pad material and the air, therefore, the substrate pads need to have a very low contact area to minimize the heat transfer between a substrate and the substrate pads. By using an equivalent thermal resistance to air, the contact area of the substrate pads may be greatly increased, which reduces pressure and therefore particle production.

In one embodiment, the total height h3 is chosen in a way that the thermal resistance of the substrate pads 103 substantially equals the thermal resistance of the air gap having a thickness of h2. The thermal resistance of the substrate pads 103 may be calculated from the total height h3 and thermal conductivity of the material from which the substrate pads 103 are made. The thermal resistance of the air gap may be calculated from the thickness h2 and the thermal conductivity of air. Therefore, the total height h3 of the substrate pads 103 may be chosen using the following equation:

$$h 3 = \frac{{K}_{pad}}{{K}_{air}} h 2$$

wherein K_{pad} and Kₐᵢᵣ are thermal conductivity of the pad material and the air respectively. It should be noted that the thermal conductivity of air may be replaced by thermal conductivity of other medium that fills between the substrate 110 and the plate 101.

In one embodiment, the air gap thickness h2 is about 0.1 mm, and the total height h3 is about 1.0 mm for substrate pads made from a perflouroelastomer.

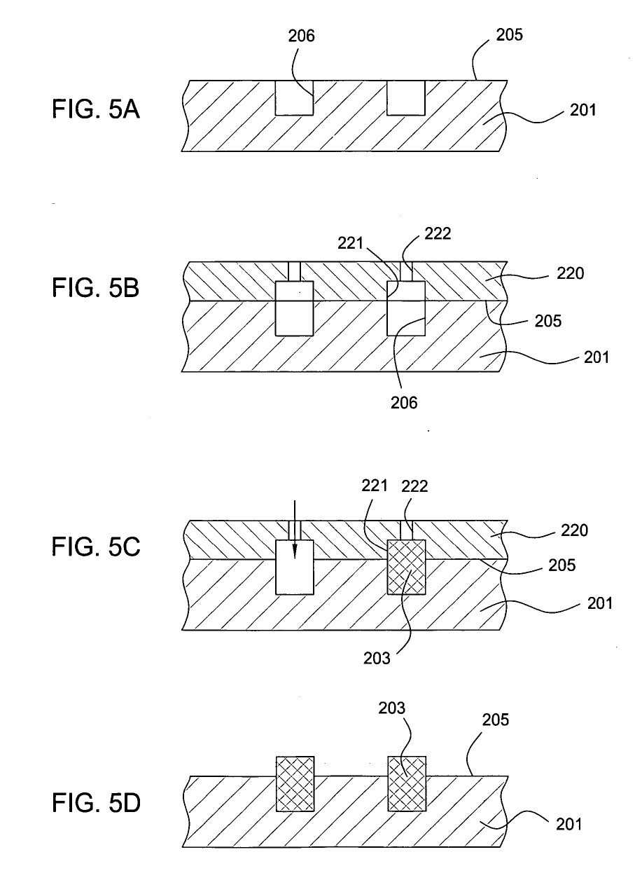

FIG. 5A-D illustrate an exemplary embodiment of manufacturing substrate pads of the present invention. As illustrated in FIG. 3A, recesses 206 configured to accommodate substrate pads are formed in an upper surface 205 of a plate body 201. The recesses 206 may be formed using an end-mill. After the recesses 206 are formed, the plate body 201 may be cleaned to get rid of any particles. Surfaces of the recesses 206 may be optionally roughed. An optional layer of adhesive may be applied on the surfaces of the recesses 206 for better adhesion. As shown in FIG. 5B, a mold 220 having recesses 221 matching the recesses 206 of the plate body 201 is provided. In one aspect, the mold 220 may have a ridge of about 4 to 10 microns near the periphery. Each of the recesses 221 has a small tunnel 222 opening to an opposite side of the mold 220. The small tunnels 222 are configured for injecting elastomer materials into the recesses 221. The mold 220 may be generally pushed down against the plate body 201 near the periphery so that the recesses 221 match the respective recesses 206 on the plate body 201. In one embodiment, a slight seal may be used between the mold 220 and the plate body 201 to prevent flash formed from squeezed out mold material. In another embodiment, laser elation may be used to remove the flash. As shown in FIG. 5C, elastomer is injected and filled to the recesses 206/221 via the small tunnels 222, forming a substrate pad 203. The mold 220 may be removed after the injected elastomer being cured for about 4 to 10 minutes at temperature of about 180° C. to 230° C.

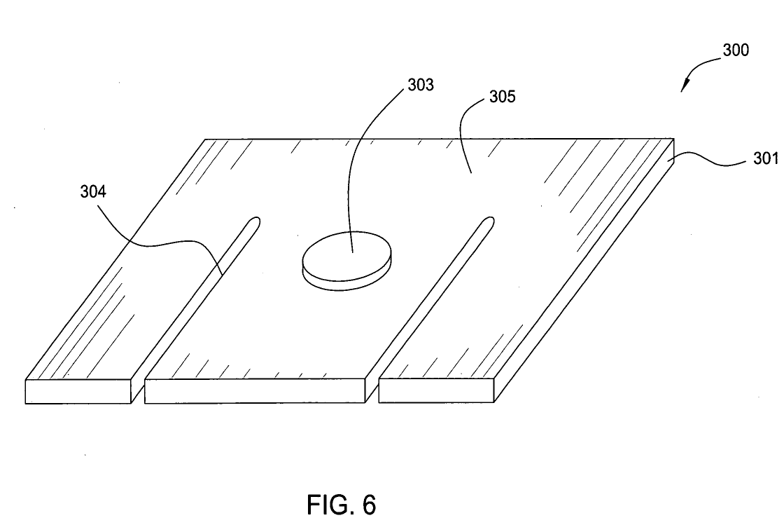

FIGS. 6-9 illustrate several embodiment of substrate support plate having substrate pads similar to the substrate pads 103 of FIG. 3.

FIG. 6 illustrates schematic view of another embodiment of a shuttle plate 300 of the present invention. The shuttle plate 300 generally comprises a plate body 301 having a substrate pad 303 protruding from an upper surface 305 of the plate body 301. Two slots 304 are generally formed on the plate body 310 configured for accommodating lifting pins. The substrate pad 303 is configured to support a substrate near the center of gravity. The shuttle plate 300 may be made from the same materials as the shuttle plate 100 of FIG. 3. The shuttle plate 300 is desirable when a substrate may encounter relatively large shrinkage, for example due to large temperature drop, while being supported or transferred by the shuttle plate 300.

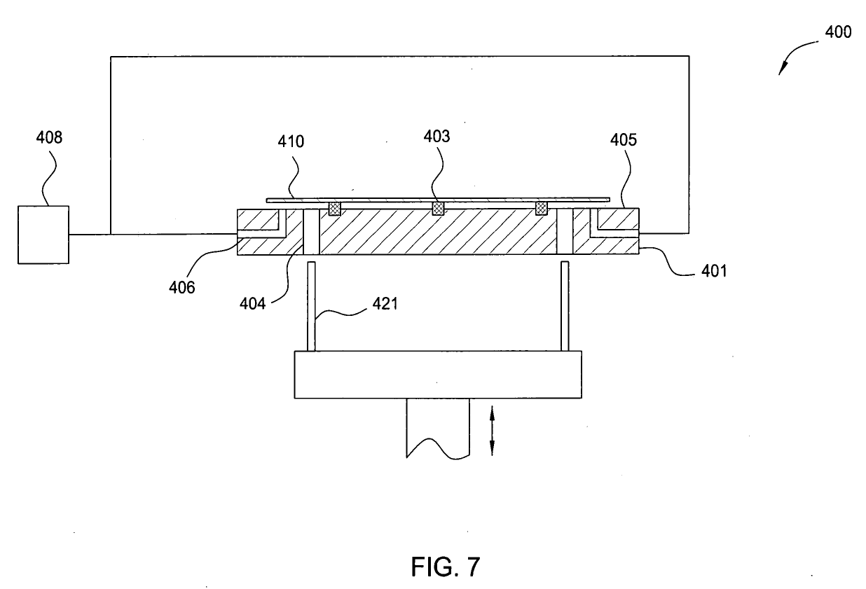

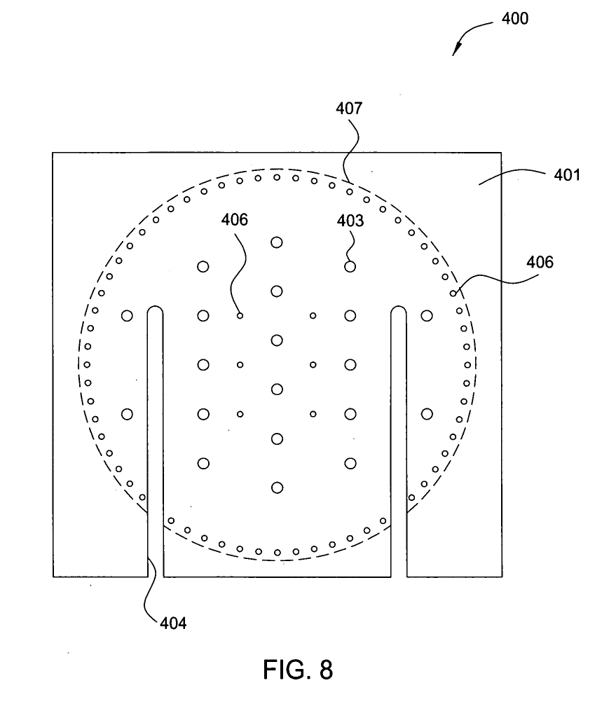

FIG. 7 illustrates a schematic sectional view of another embodiment of a shuttle plate 400 of the present invention. The shuttle plate 400 comprises a plate body 401 and a plurality of substrate pads 403 protruding from an upper surface 405 of the plate body 401. Slots 404 are formed on the plate body 401 and configured to house lift pins 421. The plate body 401 further has a plurality of vacuum ports 406 opening at the upper surface 405 and connected to a vacuum source 408. The vacuum ports 406 are configured to hold a substrate 410 in combination with the substrate pads 403. FIG. 8 illustrates a top view of the shuttle plate 400 of FIG. 7. In one embodiment, the vacuum ports 406 form a circle inside a substrate receiving area 407.

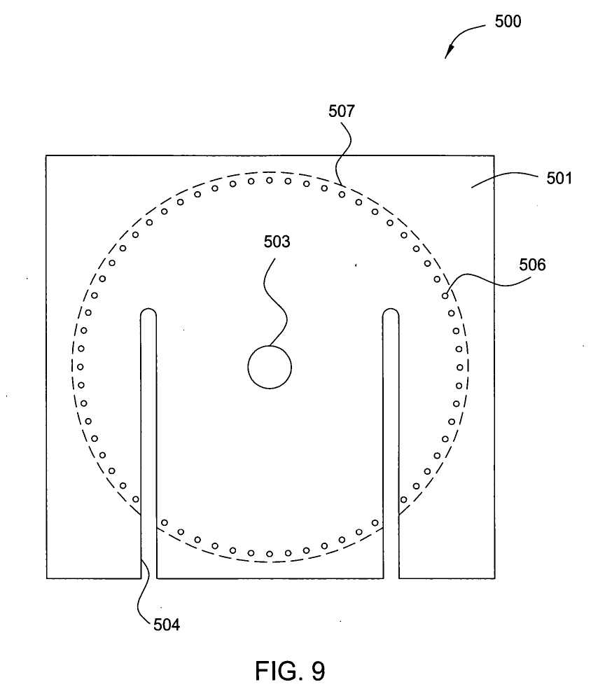

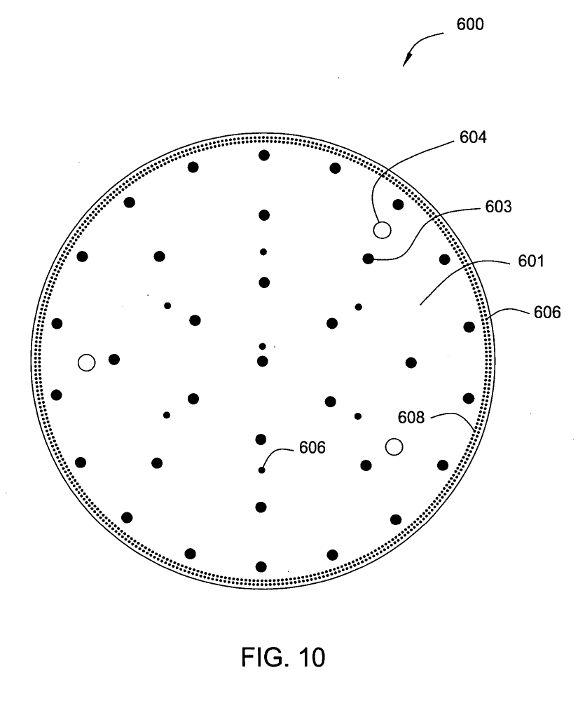

FIG. 9 illustrates yet another embodiment of a shuttle plate 500 of the present invention. The shuttle plate 500 comprises a single substrate pad 503 positioned near a center of a substrate receiving area 507. A plurality of vacuum ports 506 are distributed near a periphery of the substrate receiving area 507.

Embodiments of the present invention is generally related apparatus and method for supporting a semiconductor substrate during semiconductor processing operations. The method and apparatus for supporting a substrate of the present invention may be used in handling substrates in various situations, such as in a bake station, a chill station, a cleaning station, a substrate boat in a batch chamber, a chemical vapor deposition chamber, a robot in a cluster tool, and other situations where low contamination, high precision and/or high throughput is desired. One of ordinary skills in the art will appreciate that various components may be combined with substrate supporting apparatus of the present invention, for example vacuum and/or purge ports, electrodes for electrostatic chucking, heat exchange elements, lift pin holes, etc, for purposes related to the process.

While the foregoing is directed to embodiments of the present invention, other and further embodiments of the invention may be devised without departing from the basic scope thereof, and the scope thereof is determined by the claims that follow.

1. An apparatus for handling a substrate, comprising:
a support plate; and
at least one pad protruding an upper surface of the support plate, wherein the pad is configured to support a backside of the substrate so that the backside of the substrate is a first distance away from the upper surface of the support plate, and a thermal resistance of the pad is substantially equal to a thermal resistance of a medium between the substrate and the upper surface.

2. The apparatus of claim 1, wherein the medium is atmospheric air.

3. The apparatus of claim 1, wherein the first distance is about 0.1 mm.

4. The apparatus of claim 1, wherein the at least one pad is positioned near a center of a substrate receiving region.

5. The apparatus of claim 1, further comprising a plurality of pads similar to the at least one pad, wherein the plurality of pads are substantially evenly distributed in a substrate receiving region.

6. The apparatus of claim 1, wherein a height of the pad is chosen according to the first distance, a thermal conductivity of the medium and a thermal conductivity of the pad.

7. The apparatus of claim 1, wherein the at least one pad is formed in at least one recess on the upper surface.

8. The apparatus of claim 1, the support plate is positioned substantially horizontal.

9. The apparatus of claim 1, wherein the pad is made from an elastomer having fluorine as a major constituent.

10. The apparatus of claim 9, wherein the elastomer has on inorganic or non-fluoridated filler.

11. The apparatus of claim 9, wherein the elastomer has an nanometer sized organic filler.

12. The apparatus of claim 9, wherein the elastomer is a perfluoroelastomer.

13. An apparatus for supporting and handling a substrate, comprising:
a support plate; and
a plurality of pads formed on an upper surface of the support plate and configured to support the substrate, wherein the plurality of pads are made of an elastomer having fluorine as a major constituent.

14. The apparatus of claim 13, wherein the plurality of pads protrudes from the upper surface by a first height and have a thermal resistance of air of the first height.

15. The apparatus of claim 13, wherein the elastomer is perflouroelastomer.

16. The apparatus of claim 13, wherein the support plate has a plurality vacuum ports opening to the upper surface.

17. The apparatus of claim 13, further comprising a lift pin assembly configured to load the substrate on the support plate and to pick up the substrate from the support plate.

18. A method for handling a substrate, comprising:
providing a support plate having at least one pad formed an upper surface and a substantially uniform thermal resistance across the upper surface;
positioning the substrate on the at least one pad; and
transferring the substrate by moving the support plate.

19. The method of claim 18, wherein providing the support plate comprises:
providing the support plate having at least one recess on an upper surface;
forming the at least one pad in the at least one recess of the support plate, wherein the pad has a first height in respect to the upper surface and the pad has a thermal resistance substantially equals to a thermal resistance of air having a thickness of the first height.

20. The method of claim 18, wherein the at least one pad has a dynamic friction coefficient of about 0.4.
